(19) United States
(12) Patent Application Publication
(10) Pub. No.: US 2013/0241584 A1
(43) Pub. Date: Sep. 19, 2013

(54) POWER-ON TEST APPARATUS AND SYSTEM FOR TESTING ELECTRONIC DEVICE

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: Ze-Jun MAO, Shenzhen (CN); Hong-Ru ZHU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/720,913

(22) Filed: Dec. 19, 2012

(30) Foreign Application Priority Data
Mar. 16, 2012 (CN) 201210070014.1

(51) Int. Cl. G01R 31/00

(52) U.S. Cl. CPC G01R 31/00
USPC 324/750.01

(57) ABSTRACT

A test apparatus for executing a power-on test of an electronic device includes a setting module, an activation module, a controller, and a USB connector. The setting module includes a plurality of input keys. The activation module activates a power supply-on pin of a motherboard of the electronic device. The controller is electronically connected to the input keys and the activation module, the controller drives the activation module to activate the power supply-on pin, and controls a number of times of activation of the power supply-on pin according to a predetermined number of power-on events. The USB connector electronically connects the controller to the electronic device, the USB connector receives power-on and power-off confirmation signals from the electronic device, and transmits the signals to the controller.

### BACKGROUND

1. Technical Field

The disclosure generally relates to test apparatuses, and particularly to a power-on test apparatus and system for an electronic device.

2. Description of Related Art

A power key of electronic devices, such as a personal computer, a tablet computer, or a server, for example, is electronically connected to a power supply-ON (PS-ON) pin of a motherboard via one wire and a ground pin of the motherboard via a connection. When the electronic device is not powered and the power key is pressed, the power key electronically connects the PS-ON pin to the ground pin. Accordingly, a power supply module of the motherboard detects that the input into the PS-ON pin is low (e.g. logic 0), and powers on the electronic device.

A typical way to test a power-on/power-off performance of the electronic device, is to transmit a command to the power supply module to activate the power supply to power the electronic device. However, the aforementioned process cannot simulate a user pressing the power button to transmit a signal to the power supply module, and thus has an unsatisfactory testing effect.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 shows a block diagram of an exemplary embodiment of a power-on test system comprising a test apparatus for executing a power-on test of an electronic device.

FIG. 2 shows a schematic diagram of a first panel of a housing of the test apparatus shown in FIG. 1.

FIG. 3 shows a schematic diagram of a second panel of the housing of the test apparatus shown in FIG. 1.

FIG. 4 shows a circuit diagram of an activation module of the test apparatus shown in FIG. 1.

### DETAILED DESCRIPTION

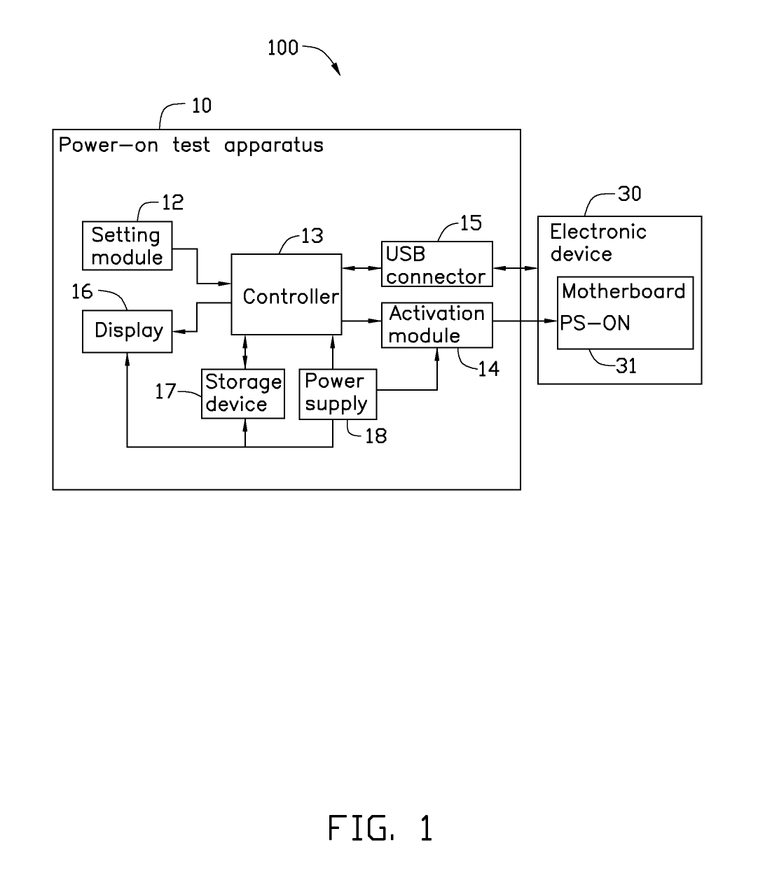

FIG. 1 shows a block diagram of an exemplary embodiment of a power-on test system 100 including a test apparatus 10 for executing a power-on test of an electronic device 30. The electronic device 30 can be a personal computer, a tablet computer, or a server. The electronic device 30 includes a motherboard 31 that includes a power supply-on pin (pin PS-ON). The electronic device 30 loads a boot program when the pin PS-ON receives a correct input.

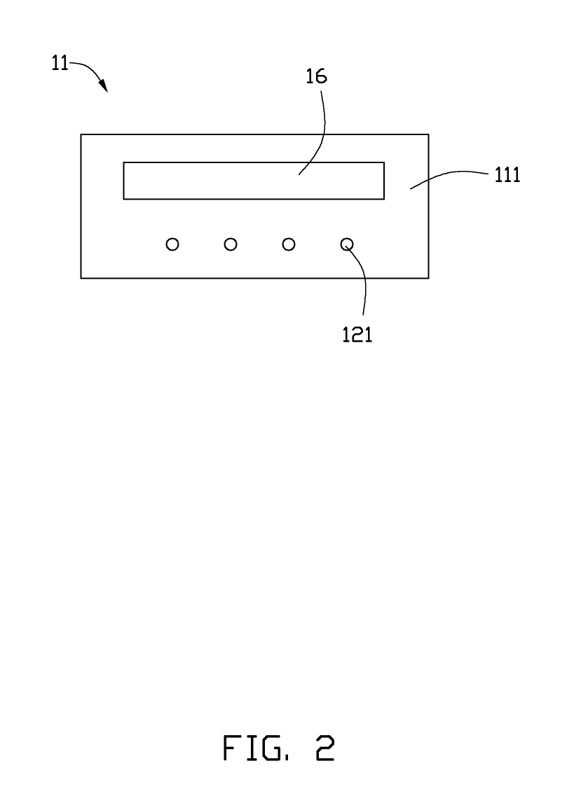

The test apparatus 10 includes a housing 11 (shown in FIG. 2), a setting module 12, a controller 13, an activation module 14, a USB connector 15, a display 16, a storage device 17, and a power supply 18. The power supply 18 powers the controller 13, the activation module 14, the USB connector 15, and the display 16. In the exemplary embodiment, an output voltage of the power supply 18 is +5V.

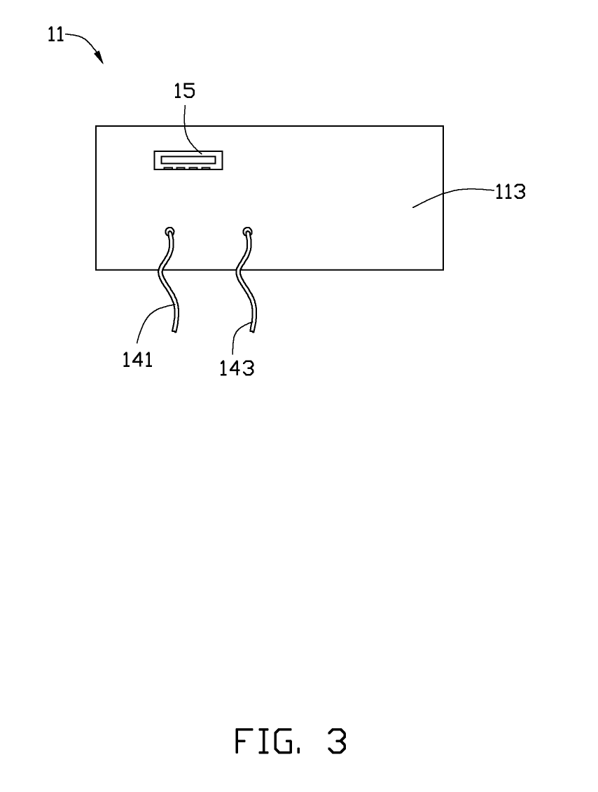

FIG. 2 shows a schematic diagram of a first panel 111 of the housing 11 of the test apparatus 10 shown in FIG. 1. FIG. 3 shows a schematic diagram of a second panel 113 of the housing 11 of the test apparatus 10 shown in FIG. 1.

The setting module 12 includes a plurality of input keys 121 electronically connected to the controller 13. The input keys 121 are spaced on the first panel 111. Manipulation of combinations of the input keys 121 can input a predetermined number of power-on events, and a predetermined power-off period of time. For example, the keys 121 include a menu key, a save key, a page up (addition) key, and a page down (subtraction) key, allowing a user to input the predetermined number of power-on events and the predetermined power-off period of time.

The controller 13 is electronically connected to the activation module 14, the USB connector 15, the display 16, the storage device 17, and the power supply 18. The controller 13 controls a number of times of activation and activation durations of the activation module 14 according to the predetermined number of power-on events and the predetermined power-off period of time, thereby controlling a number of power-on times and power-off durations of the electronic device 30. In other words, the controller 13 controls the activation module 14 to enable the pin PS-ON according to the predetermined number of power-on events.

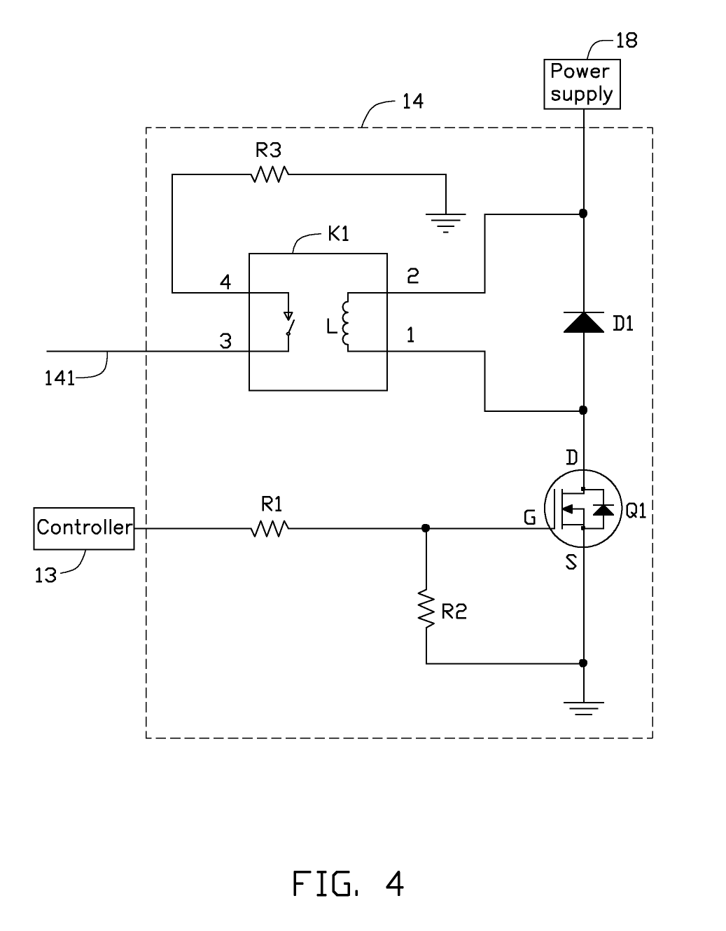

FIG. 4 shows a circuit diagram of the activation module 14 of the test apparatus 10 shown in FIG. 1. The activation module 14 includes a first cable 141 (shown in FIG. 3), a relay K1, an electronic switch Q1, a diode D1, a first voltage dividing resistor R1, and a second resistor R2. The first cable 141 exits from the housing 11 via the second panel 113. The relay K1 is electronically connected to the pin PS-ON of the electronic device 30 via the first cable 141. The controller 13 switches on the electronic switch Q1 to close the relay K1, such that the relay K1 enables the pin PS-ON via the first cable 141, to power on the electronic device 30.

In the exemplary embodiment, the electronic switch Q1 is an N-channel metal-oxide-semiconductor field-effect transistor (MOSFET), a gate G of the N-channel MOSFET is electronically connected to the controller 13 via the first voltage dividing resistor R1, a source S of the N-channel MOSFET is grounded, and a drain D of the N-channel MOSFET is electronically connected to the relay K1. The second voltage dividing resistor R2 is connected between ground and a node between the first voltage dividing resistor R1 and the gate G of the N-channel MOSFET. The relay K1 is an electromagnetic relay, which includes a coil L, two control terminals land 2, and two connecting terminals 3 and 4. The drain D of the N-channel MOSFET electronically connects the coil L to the power supply 18 via the two control terminals 1 and 2. The two connecting terminals 3 and 4 are connected when a current flows through the coil L. The two connecting terminals 3 and 4 are disconnected when no current flows through the coil L. An anode of the diode D1 is electronically connected to the control terminal 1, a cathode of the diode D1 is electronically connected to the control terminal 2. The diode D1 discharges the coil L when the electronic switch Q1 is switched off.

The first electronic switch Q1 can be an NPN type bipolar junction transistor (BJT) comprising a base, emitter, and collector corresponding to the gate G, the source S and the drain D of the N-channel MOSFET, respectively.

In one embodiment, the pin PS-ON is activated by a low level voltage (logic 0). One of the two connecting terminals 3 and 4 (e.g. the connecting terminal 3 shown in FIG. 4) is electronically connected the pin PS-ON via the first cable 141, the other one of the two connecting terminals 3 and 4 (e.g. the connecting terminal 4 shown in FIG. 4) is grounded via a pull-down resistor R3. The controller 13 can switch on the electronic switch Q1 by outputting a high level voltage (logic 1) to the electronic switch Q1. At this time, a current flows through the coil L, the two connecting terminals 3 and 4 become connected to each other, the pin PS-ON is grounded and is thereby enabled, the electronic device 30 under test is thus powered on. After the high level voltage has continued for a predetermined duration (e.g. two seconds), the controller 13 outputs a low level voltage (logic 0) to switch off the electronic switch Q1, thereby disconnecting the connecting terminal 3 from the connecting terminal 4.

In another embodiment, the activation module 14 further includes a second cable 143 (shown in FIG. 3). One of the two connecting terminals 3 and 4 is electronically connected to the pin PS-ON via the first cable 141, the other one of the connecting terminals 3 and 4 is electronically connected to a ground of the electronic device 30. When the two connecting terminals 3 and 4 become connected, the pin PS-ON is thus grounded via the ground connection of the electronic device 30.

In another embodiment, the pin PS-ON can be activated by a high level voltage (logic 1). At this time, one of the two connecting terminals 3 and 4 is electronically connected to the pin PS-ON via the first cable 141, the remaining terminal is electronically connected to the power supply 18 via a pull-up resistor (not shown). When the two connecting terminals 3 and 4 become connected, the pin PS-ON is sent high (+5V) and is thereby enabled.

The USB connector 15 is positioned on the second panel 113. The USB connector 15 is electronically connected to the electronic device 30 via a USB cable (not shown). The connector 15 electrically connects the controller 13 to the electronic device 30 to provide input/output processing, through a physical connection. The display 16 is positioned on the first panel 111, and displays testing results of the electronic device 30, the predetermined number of power-on events, the predetermined power-off period of time, and actual number of power-on and power-off events. The storage device 17 receives and stores the predetermined number of power-on events and the predetermined power-off period of time from the input module 12 via the controller 13, and records the actual number of power-on and power-off events of the electronic device 30.

When the electronic device 30 has been powered on or has been powered off, the electronic device 30 outputs a power-on confirmation signal or a power-off confirmation signal accordingly. The USB connector 15 receives the power-on confirmation signal and the power-off confirmation signal, which are transmitted to the controller 13. In the exemplary embodiment, when electronic device 30 is powered on and has continued for a predetermined power-on period of time, the electronic device 30 automatically loads a shut down program, to be powered off. The predetermined power-on period of time can be set by programming the electronic device 30, or by inputs from the input module 12, to be transmitted to the electronic device 30 via the controller 13.

In use, the working process of the system 100 can be carried out by, but is not limited to, the following steps. The controller 13 controls the electronic device 30 to be powered on via the activation module 14. After the electronic device 30 is powered on, the electronic device 30 outputs a power-on confirmation signal to the controller 13, the storage device 17 increments the number of power-on events by one. After reaching the predetermined power-on period of time, the electronic device 30 automatically loads a shut down program and transmits a power-off confirmation signal to the controller 13. After the controller 13 receives the power-off confirmation signal and has reached the predetermined power-off period of time, the test apparatus 10 repeats the aforementioned process until the number of power-on events has reached the predetermined number, the test apparatus 10 then finishes the power-on testing of the electronic device 30. If the controller 13 has not received a power-on confirmation signal or a power-off confirmation signal within a certain period of time, the controller 13 determines that the electronic device 30 does not pass the test, and displays the test results.

In the power-on test system 10 for testing the electronic device 30 of the disclosure, the activation module 14 activates the pin PS-ON of the electronic device 30, and a power supply module of the electronic device 30 powers on the electronic device 30 when the power supply module detects that the pin PS-ON is enabled. The activation module 14 thus simulates a power key of the electronic device 30 to activate the pin PS-ON, which provides more accurate test results from the electronic device 30.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A test apparatus, comprising:
a setting module comprising a plurality of input keys;
an activation module activating a power supply-on pin of a motherboard of an electronic device, to power on the electronic device;
a controller electronically connected to the input keys and the activation module, the controller driving the activation module to activate the power supply-on pin, and controlling a number of times of activation of the power supply-on pin according to a predetermined number of power-on events, the predetermined number of power-on events inputted using the plurality of input keys; and
a USB connector electronically connecting the controller to the electronic device, the USB connector receiving a power-on confirmation signal and a power-off confirmation signal from the electronic device, and transmitting the power-on and power-off confirmation signals to the controller;
wherein the controller determines a test result according to receipt of the power-on and power-off confirmation signals.

2. The test apparatus of claim 1, wherein the activation module comprises a first cable, an electronic switch electronically connected to the controller, and a relay electronically connected to the electronic switch, the relay electronically connected to the power supply-on pin of the electronic device via the first cable, the controller turns the electronic switch on to close the relay, thereby activating the power supply-on pin.

3. The test apparatus of claim 2, further comprising a power supply powering the controller and the USB connector, wherein the electronic switch is a N-channel metal-oxide-semiconductor field-effect transistor (MOSFET), a gate of the N-channel MOSFET is electronically connected to the controller, a source of the N-channel MOSFET is grounded, the relay comprises a coil and two connecting terminals, the coil is electronically connected between a drain of the N-channel MOSFET and the power supply, one of the two connecting terminals is electronically connected to the power supply-on pin of the electronic device via the first cable.

4. The test apparatus of claim 3, wherein when the power supply-on pin is activated by a low signal, the other one of the two connecting terminals is grounded.

5. The test apparatus of claim 3, wherein when the power supply-on pin is activated by a high signal, the other one of the two connecting terminals is electronically connected to the power supply.

6. The test apparatus of claim 3, wherein the activation module further comprises a second cable, when the power supply-on pin is activated by a low signal, the other one of the two connecting terminals is electronically connected to a grounded pin of the motherboard of the electronic device via the second cable.

7. The test apparatus of claim 3, wherein the activation module further comprises a diode, an anode of the diode is electronically connected to the drain of the N-channel MOSFET, the cathode of the diode is electronically connected to the power supply.

8. The test apparatus of claim 1, wherein when the controller does not receive the power-on confirmation signal or the power-off confirmation signal within a corresponding predetermined period of time, the controller determines the electronic device does not pass the test.

9. The test apparatus of claim 1, further comprising a display electronically connected to the controller, the display displays the test result, the predetermined number of power-on events, and the actual number of power-on and power-off events.

10. The test apparatus of claim 1, further comprising a storage device electronically connected to the controller, the storage device stores the predetermined number of power-on events, and counts and stores the actual number of power-on and power-off events.

11. A test system, comprising:
an electronic device comprising a motherboard, the motherboard comprising a power supply-on pin; and
a test apparatus comprising:
a setting module comprising a plurality of input keys;
an activation module activating a power supply-on pin of a motherboard of the electronic device, to power on the electronic device;
a controller electronically connected to the input keys and the activation module, the controller driving the activation module to activate the power supply-on pin, and controlling a number of times of activation of the power supply-on pin according to a predetermined number of power-on events, the predetermined number of power-on events inputted using the plurality of input keys; and
a USB connector electronically connecting the controller to the electronic device, the USB connector receiving a power-on confirmation signal and a power-off confirmation signal from the electronic device, and transmitting the power-on and power-off confirmation signals to the controller;
wherein the controller determines a test result according to receipt of the power-on and power-off confirmation signals.

12. The test system of claim 11, wherein the electronic device automatically loads a shut down program when the electronic device is powered on and is reached to a predetermined power-on period of time.

13. The test apparatus of claim 11, wherein the activation module comprises a first cable, an electronic switch electronically connected to the controller, and a relay electronically connected to the electronic switch, the relay electronically connected to the power supply-on pin of the electronic device via the first cable, the controller turns the electronic switch on to close the relay, thereby activating the power supply-on pin.

14. The test apparatus of claim 13, further comprising a power supply powering the controller and the USB connector, wherein the electronic switch is a N-channel metal-oxide-semiconductor field-effect transistor (MOSFET), a gate of the N-channel MOSFET is electronically connected to the controller, a source of the N-channel MOSFET is grounded, the relay comprises a coil and two connecting terminals, the coil is electronically connected between a drain of the N-channel MOSFET and the power supply, one of the two connecting terminals is electronically connected to the power supply-on pin of the electronic device via the first cable.

15. The test apparatus of claim 14, wherein when the power supply-on pin is activated by a low signal, the other one of the two connecting terminals is grounded.

16. The test apparatus of claim 14, wherein when the power supply-on pin is activated by a high signal, the other one of the two connecting terminals is electronically connected to the power supply.

17. The test apparatus of claim 14, wherein the activation module further comprises a second cable, when the power supply-on pin is activated by a low signal, the other one of the two connecting terminals is electronically connected to a grounded pin of the motherboard of the electronic device via the second cable.

18. The test apparatus of claim 14, wherein the activation module further comprises a diode, an anode of the diode is electronically connected to the drain of the N-channel MOSFET, the cathode of the diode is electronically connected to the power supply.

19. The test apparatus of claim 11, wherein when the controller does not receive the power-on confirmation signal or the power-off confirmation signal within a corresponding predetermined duration, the controller determines the electronic device does not pass the test.

20. The test apparatus of claim 11, further comprising a display electronically connected to the controller, the display displays the test result, the predetermined number of power-on events, and the actual number of power-on and power-off events.
